(19) United States
(12) Patent Application Publication
(10) Pub. No.: US 2021/0249600 A1
(43) Pub. Date: Aug. 12, 2021

(54) PHASE CHANGE MEMORY WITH A CARBON BUFFER LAYER

(71) Applicant: MACRONIX INTERNATIONAL CO., LTD., HSINCHU (TW)

(72) Inventors: Wei-Chih CHIEN, TAIPEI (TW); Hsiang-Lan LUNG, ARDSLEY, NY (US)

(73) Assignee: MACRONIX INTERNATIONAL CO., LTD., HSINCHU (TW)

(21) Appl. No.: 16/787,371

(22) Filed: Feb. 11, 2020

(51) Int. Cl. H01L 45/00; H01L 27/24

(52) U.S. Cl. CPC H01L 45/149; H01L 27/2427; H01L 45/1253

(57) ABSTRACT

A memory element comprises a carbon deposit, such as a carbon buffer layer, on a body of phase change memory material, disposed between first and second electrodes. A carbon deposit is found to improve endurance of phase change memory cells by five orders of magnitude or more. Examples include “mushroom” style memory elements, as well as other types including 3D arrays of cross-point elements.

### PARTIES TO A JOINT RESEARCH AGREEMENT

International Business Machines Corporation, a New York corporation, and Macronix International Corporation, Ltd., a Taiwan corporation, are parties to a Joint Research Agreement.

### BACKGROUND OF THE INVENTION

### Field of the Invention

The present invention relates to memory devices including phase change-based memory materials, including chalcogenide-based materials and other programmable resistance materials, and methods for manufacturing such devices.

### Description of Related Art

Phase change based memory materials, like chalcogenide based materials and similar materials, can be caused to change phase between an amorphous state and a crystalline state by application of electrical current at levels suitable for implementation in integrated circuits. The generally amorphous state is characterized by higher electrical resistivity. These materials are the basis for integrated circuit phase change memory devices, and other memory technologies.

The change from the amorphous to the crystalline state is generally a lower current operation. The change from crystalline to amorphous, referred to as reset herein, is generally a higher current operation, which includes a short high current density pulse to melt or breakdown the crystalline structure, after which the phase change material cools quickly, quenching the phase change process and allowing at least a portion of the phase change material to stabilize in the amorphous state.

One problem with very small dimension phase change devices involves endurance. Specifically, the resistance of memory cells made using phase change materials in a set state can drift as the composition of the phase change material changes with time over the life of the device.

Accordingly, it is desirable to provide a memory cell structure having more stable operation over the life of the device, and to provide for higher speed operations.

### SUMMARY OF THE INVENTION

A memory technology is described that includes a memory element comprising a carbon deposit, such as a carbon buffer layer, on a body of phase change memory material, disposed between first and second electrodes. A carbon deposit as described herein is found to improve endurance of phase change memory cells by five orders of magnitude or more. the technology can be deployed with “mushroom” style memory elements, as well as other types, including 3D arrays of cross-point elements.

A method of manufacturing memory arrays including carbon deposits is described herein.

An integrated circuit utilizing the memory technology is described.

Other aspects and advantages of the present invention can be seen on review of the drawings, the detailed description and the claims, which follow.

### BRIEF DESCRIPTION OF THE DRAWINGS

FIG. 1 illustrates structure of a “mushroom” type memory element including a carbon buffer layer.

FIG. 2 illustrates structure of a “mushroom” type memory element including a carbon buffer layer according to one alternative.

FIG. 3 illustrates an “active in via” type memory element structure including a carbon buffer layer.

FIG. 4 illustrates structure of a cross-point memory cell with a memory element including a carbon buffer layer.

FIG. 5 illustrates structure of a “pore” type memory element including a carbon buffer layer.

FIG. 6 is a simplified flowchart of a manufacturing process described herein.

FIG. 7 is a schematic diagram of an array of one transistor/one memory element memory cells including buffer layers as described herein.

FIG. 8 is a simplified block diagram of an integrated circuit memory device including phase change memory cells as described herein.

### DETAILED DESCRIPTION

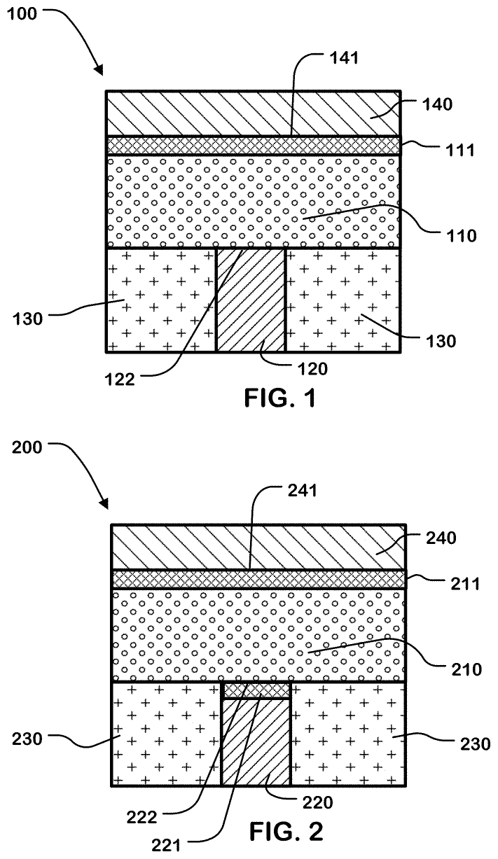

A detailed description of embodiments of new memory technology is provided with reference to FIGS. 1-8.

FIG. 1 illustrates a “mushroom” type memory element 100 having a first electrode 120 extending through dielectric 130, comprising a body 110 of phase change material, a carbon deposit 111, in the form of a continuous layer, in this embodiment contacting the body 110, and a second electrode 140 on the body 110. The first electrode 120 contacts the body of phase change material over a first contact area 122, and the second electrode contacts the carbon deposit over a second contact area 141. In a mushroom type memory element as illustrated, the first contact area 122 is smaller than the second contact area 141, such as at least 50% smaller, and in some embodiments at least 90% smaller. The first electrode 120 is coupled to a terminal of an access device (not shown) such as a diode or switch, while the second electrode 140 is coupled to a bit line and can be part of the bit line (not shown). The small first contact area 122 between the body of phase change material and the first electrode 120 and a relatively larger second contact area 11 between the carbon deposit 111 and the second electrode 140, results in higher current densities with small absolute current values in an active region of the body 110 proximal to the first electrode 120. In one example configuration, the first electrode 120 has a first contact area 122 on the order of 15 to 30 square nanometers, while the second electrode may have a contact area 141 that is continuous along a conductive line, acting as a bit line or local bit line, with the body of phase change material formed so as to line the bottom side of the conductive line continuously along a length that of the conductive line, with first electrodes (like 120) of a plurality of mushroom memory elements contacting the body distributed along the length.

The carbon deposit 111 can be a sputter deposited formation having a thickness less than 15 nm, such as about 10 nm, contacting the body of phase change material. The carbon deposit 111 can be the material that results from sputtering using a “pure” carbon target on the body of phase change material after back-end-of-line (BEOL) processing, which can include annealing cycles. A “pure” carbon target is a target that is on the order of 99% or more pure carbon. The carbon deposit 111 can consist essentially of carbon in some embodiments, with small amounts of materials including materials diffused from adjacent structures without destroying the ability of the carbon deposit 111 to improve endurance and inhibit phase separation and migration of the elements in the body of phase change material.

In some embodiments, the carbon deposit 111 can included additives, such as silicon. The carbon deposit 111 forms a stable, low resistance layer (not consuming much of the voltage headroom) that suppresses phase separation of components of the phase change material, such as GeₓSb_{y}Te_{z} (GST), in fast device endurance testing, perhaps may damp current peaks and hot spots that may damage the phase change material. The carbon deposit 111 can be a conductive form of carbon (e.g. hexagonal, amorphous, a combination of forms). The thickness and resistivity are such that only a small resistor is formed in series with the memory body, so as to consume a small portion of the voltage headroom across the memory cell.

The body of phase change material can have a thickness in the region of the first contact area 122 selected according to operating characteristics of the particular materials, and can be on the order of 50 nm, for example. The thickness of the phase change material depends on the design and operating conditions of the cell structure.

The phase change material of memory body 110 in this example can be GeₓSb_{y}Te_{z} material, and can be doped with 10 to 20 atomic percent (at %) silicon oxide, with bulk stoichiometry x=2, y=2 and z=5, with a carbon deposit 111 on the top side.

Other chalcogenides and phase change alloy materials may be used as well. The phase change materials used in the embodiment described herein consist of silicon oxide and Ge₂Sb₂Te₅. Representative chalcogenide material can have a bulk stoichiometry characterized as follows: GeₓSb_{y}Te_{z}, where x:y:z=2:2:5. Other compositions can be used with x: 0˜5; y: 0˜5; z: 0˜10. GeₓSb_{y}Te_{z} with doping, such as N-, Si-, Ti-, or other element doping, may also be used. GeₓSb_{y}Te_{z} with doping, such as silicon oxide or silicon nitride or both can be used, where x:y:z=2:2:5; x:y:z=2:2:6; x:y:z=2:3:5; and x:y:z=2:4:5.

Other phase change alloys including chalcogenides may be used as well. Chalcogens include any of the four elements oxygen (O), sulfur (S), selenium (Se), and tellurium (Te), forming part of group VIA of the periodic table. Chalcogenides comprise compounds of a chalcogen with a more electropositive element or radical. Chalcogenide alloys comprise combinations of chalcogenides with other materials such as transition metals. A chalcogenide alloy usually contains one or more elements from group IVA of the periodic table of elements, such as germanium (Ge) and tin (Sn). Often, chalcogenide alloys include combinations including one or more of antimony (Sb), gallium (Ga), indium (In), and silver (Ag). Many phase change based memory materials have been described in technical literature, including alloys of: Ga/Sb, In/Sb, In/Se, Sb/Te, Ge/Te, Ge/Sb/Te, In/Sb/Te, Ga/Se/Te, Sn/Sb/Te, In/Sb/Ge, Ag/In/Sb/Te, Ge/Sn/Sb/Te, Ge/Sb/Se/Te and Te/Ge/Sb/S. In the family of Ge/Sb/Te alloys, a wide range of alloy compositions may be workable.

Chalcogenides and other phase change materials are doped with impurities in some embodiments to modify conductivity, transition temperature, melting temperature, and other properties of memory elements using the doped chalcogenides. Representative impurities used for doping chalcogenides include nitrogen, silicon, oxygen, silicon dioxide, silicon nitride, copper, silver, gold, aluminum, aluminum oxide, tantalum, tantalum oxide, tantalum nitride, titanium and titanium oxide.

The first and second electrodes 120, 140 may comprise, for example, TiN or TaN. Alternatively, the first and second electrodes 220, 240 may each be W, WN, TiAlN or TaAlN, or comprise, for further examples, one or more elements selected from the group consisting of doped-Si, Si, C, Ge, Cr, Ti, W, Mo, Al, Ta, Cu, Pt, Ir, La, Ni, N, O, and Ru and combinations thereof.

In the illustrated embodiment the dielectric 130 comprises silicon nitride. Alternatively, other dielectric materials, such as silicon oxides, may be used.

The contact area 122 between the first electrode 120 and the body 110 of phase change material has a width (which in some embodiments is a diameter) less than that of the contact area 141 between the body 110 of phase change material and the second electrode 140. Thus, current is concentrated in the portion of the memory body 110 proximal to or adjacent the first electrode 120, resulting in the active region in which the phase change kinetics are confined during operation.

The first electrode 120 extends through dielectric 130 to underlying access circuitry (not shown). The underlying access circuitry can be formed by standard processes as known in the art, and the configuration of elements of the access circuitry depends upon the array configuration in which the memory cells described herein are implemented. Generally, the access circuitry may include access device switches, such as Ovonic threshold switches, FET transistors or bipolar transistors. Also, access devices such as diodes can be utilized. Other elements of access circuitry include word lines and sources lines, conductive plugs, and doped regions used as conductors within a semiconductor substrate.

Comparative testing was done on a memory element like that shown in FIG. 1, using fast switching GeₓSb_{y}Te_{z}, where x:y:z=2:2:5, with silicon additive at about 5 at %, with and without the carbon buffer layer. Endurance cycling was executed using a 100 ns reset box pulse, with a set pulse tail of about 1 μs.

Without the carbon buffer layer, the memory element shorts out after about 1×10⁵ cycles. This electrical short circuit of the memory element is believed to be a result of migration of Te toward the second electrode 140, and migration of Ge and Sb toward the first electrode 120, perhaps caused by high transient currents encountered during the set and reset cycling of the memory element.

With a 10 nm carbon deposit 111 as described, cycling endurance improved by a surprising and unexpected amount, more than five (5) orders of magnitude to beyond 1×10¹⁰ cycles. This enables utilization of fast switching materials, while providing very high endurance. Faster switching reduces the amount of time the memory element is under stress during the lifetime of the device.

Analysis of the body of phase change material after endurance cycling showed that the migration of Ge/Sb for the bottom electrode, and migration of Te toward the top electrode were inhibited.

FIG. 2 illustrates an alternative structure including two carbon deposits in the memory element. FIG. 2 illustrates a “mushroom” type memory element 200 having a first electrode 220 extending through dielectric 230, a bottom carbon deposit 221 in the form of a continuous layer, in this embodiment on the top surface of first electrode 220, a body 210 of phase change material on the bottom carbon deposit 221, a top carbon deposit 211 in the form of a continuous layer, in this embodiment contacting the body 210 and a second electrode 240 on the body 210. The bottom carbon deposit 221 is co-extensive with the top surface of the first electrode 220, and contacts the body of phase change material over a first contact area 222, and the second electrode contacts the top carbon deposit 211 over a second contact area 241. In mushroom type memory elements, as illustrated, the first contact area 222 is smaller than the second contact area 241, such as at least 50% smaller, and in some embodiments at least 90% smaller. The first electrode 220 is coupled to a terminal of an access device (not shown) such as a diode or switch, while the second electrode 240 is coupled to a bit line and can be part of the bit line (not shown). The small first contact area 222 between the body of phase change material and the first electrode 220, and a relatively larger second contact area 241 between the top carbon deposit 211 and the second electrode 240, results in higher current densities with small absolute current values in an active region of the body 210 proximal to the first electrode 220. In one example configuration, the first electrode 220 and bottom carbon deposit have a first contact area 222 on the order of 15 to 30 square nanometers, while the second electrode may have a contact area that is continuous along conductive line acting as a bit line or local bit line, with the body of phase change material formed so as to line the bottom side of the conductive line continuously along a length that of the conductive line, with more than one first electrode 220 contacting the body distributed along the length.

Thus, embodiments including top and bottom carbon deposits (211, 221) are shown. Also, embodiments including only a bottom carbon deposit 221 may be implemented.

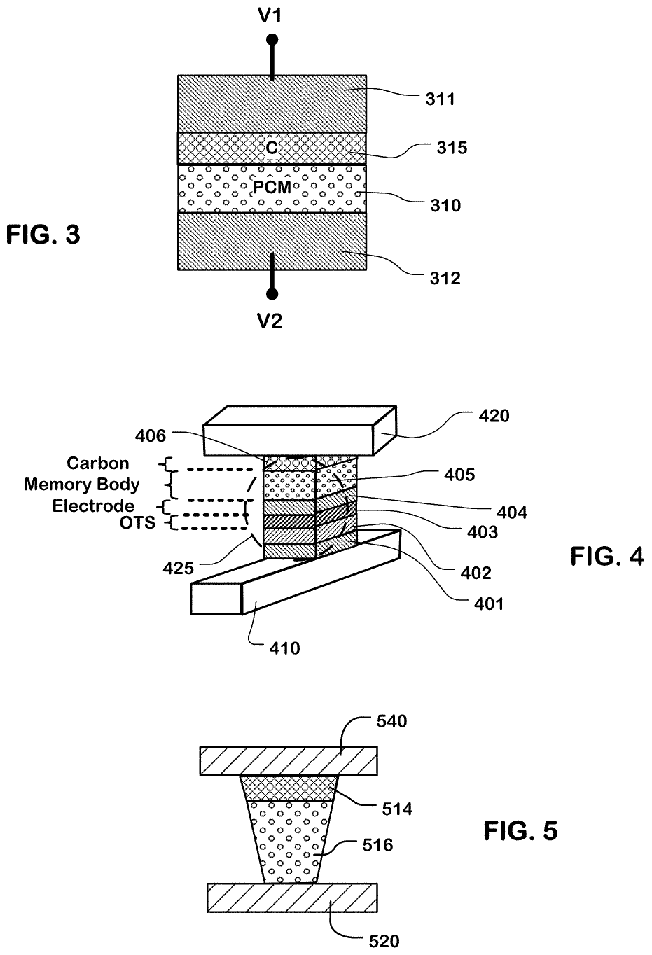

FIGS. 3-5 illustrate alternative memory element structures that comprise carbon deposits as described herein. The materials described above with reference to the elements of FIGS. 1 and 2 may be implemented in the memory cells of FIGS. 3-5, and thus a detailed description of these materials is not repeated.

FIG. 3 illustrates a cross-sectional view of a pillar-shaped memory element have an “active in via” structure. The memory element includes a body 310 of phase change material between first and second electrodes 312, 311, with a carbon deposit 315 formed between the body 310 of phase change material and the second electrode 311. The memory element has a width substantially the same, in this example, as that of the first and second electrodes 312, 311 to define a multi-layer pillar surrounded by dielectric (not shown), in operation, as current passes between the first and second electrodes 312, 311 through the carbon deposit 315 and the memory element body 310.

FIG. 4 illustrates an example memory cell 425 which comprises a multi-layer pillar disposed in the cross-point of a first access line 410 and a second access line 420.

The pillar in this example includes a bottom electrode layer 401, such as a metal, metal nitride, a doped semiconductor, or the like, on the first access line 410.

A buffer layer 402 is disposed on the bottom electrode layer 401. In some embodiments, the buffer layer 402 can be a composition such as silicon and carbon. The buffer layer 402 can be, for example, 15 to 30 nm thick.

An OTS switching layer 403 is disposed on the buffer layer 402. The OTS switching layer 403 can comprise an OTS material such as, for some examples, AsSeGeSi, AsSeGeSiC, AsSeGeSiN, AsSeGeSiTe, AsSeGeSiTeS, AsTeGeSi, AsTeGeSiN, and other available OTS materials. The OTS switching layer can be for example, 15 to 45 nm thick, and preferably less than 50 nm thick.

A buffer layer 404 is disposed on the OTS switching layer 403, and can be called a capping layer for the OTS material. The buffer layer 404 can be a barrier layer that comprises a composition of silicon and carbon. The buffer layer 404 can be, for example, 15 to 30 nm thick.

A memory material layer 405 is disposed on the buffer layer 404. The memory material can comprise a programmable resistance material. In embodiments of the technology, the memory material comprises a phase change memory material, such as GST (e.g., Ge2Sb2Te5), silicon oxide doped GST, nitrogen doped GST, silicon oxide doped GaSbGe, or other phase change memory materials. In some embodiments, other programmable resistance memory elements can be implemented, such as metal-oxide resistive memories, magnetic resistive memories and conducting-bridge resistive memories, or other types of memory devices. The memory material layer 405 can have a thickness selected according to the particular material utilized. The memory material layer can be a body of phase change material, an example range of thicknesses as discussed above.

A carbon deposit 406 is disposed on a top surface of the memory material layer 405. The carbon deposit 406 can be, for example, a continuous layer 5 to 15 nm thick.

The first access lines (bit lines) and the second access lines (word lines) can comprise a variety of metals, metal-like materials and doped semiconductors, or combinations thereof. Embodiments of the first and second access lines can be implemented using one or more layers of materials like tungsten (W), aluminum (Al), copper (Cu), titanium nitride (TiN), tantalum nitride (TaN), tungsten nitride (WN), doped polysilicon, cobalt silicide (CoSi), Tungsten silicide (WSi), TiN/W/TiN, and other materials. For example, the thicknesses of the first access lines and the second access lines can range from 10 to 100 nm. In other embodiments, the first access lines and the second access lines can be very thin, or much thicker. The material selected for the second access lines is preferably selected for compatibility with the carbon deposit 406 in this example, or otherwise with the memory cell 425. Likewise, the material selected for the first access lines is preferably selected for compatibility with the electrode material of the bottom electrode layer 401, or otherwise with the memory cell 425.

In another embodiment, a bottom electrode layer like that shown in FIG. 3 has a smaller contact surface than the surface of the switching layer. As such, an increased current density can be achieved. Also, in another embodiment, a carbon deposit can be disposed between the body of phase change material and the OTS switching layer 403.

FIG. 5 illustrates a cross-sectional view of a fourth memory element having a pore-type structure. The memory element has a body 516 of phase change material surrounded by dielectric (not shown) in electrical series between first and second electrodes 520, 540 at top and bottom surfaces, respectively. A carbon deposit 514 is formed on a top surface of the body 516 of phase change material as discussed above. The body 516 of phase change material can have a width proximal the top electrode 514 that is greater than the width proximal the first electrode 520.

As will be understood, the present invention is not limited to the memory cell structures described herein and generally includes memory cells including a body of phase change material with carbon deposits configured as described herein.

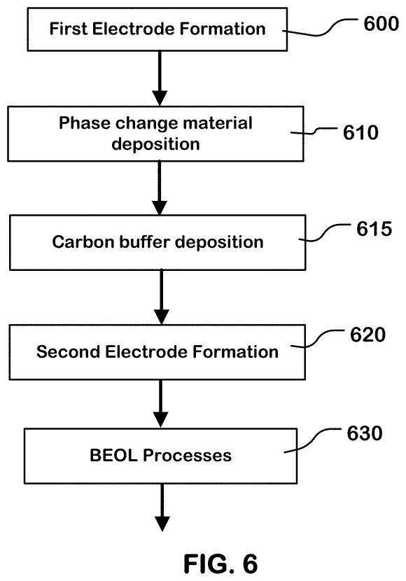

FIG. 6 illustrates a process flow diagram of a manufacturing process for manufacturing a memory cell as shown in FIG. 6.

At step 600, the first electrode 120 having a contact area 122 is formed, extending through dielectric 130. In the illustrated embodiment, the first electrode 120 comprises TiN and the dielectric 130 comprises SiN. In some embodiments, the contact area 122 of the first electrode 120 has a sub-lithographic width or diameter.

The first electrode 120 and the dielectric 130 can be formed, by a number of processes. For example, a layer of electrode material can be formed on the top surface of access circuitry (not shown), followed by patterning of a layer of photoresist on the electrode layer using standard photolithographic techniques so as to form a mask of photoresist overlying the location of the first electrode 120. Next, the mask of photoresist is trimmed using, for example, oxygen plasma to form a mask structure having sub-lithographic dimensions overlying the location of the first electrode 120. Then, the layer of electrode material is etched using the trimmed mask of photoresist, thereby forming the first electrode 120 having a sub-lithographic diameter. Next dielectric 130 is formed and planarized.

At step 610, a body of phase change material having a bulk stoichiometry (e.g. doped Ge₂Sb₂Te₅ material having 5 to 10 at % silicon) is deposited on the first electrode 120 and dielectric 130. The deposition of Ge₂Sb₂Te₅ and silicon may be carried out by co-sputtering of a GST target with for one example, a DC power of 10 Watts and an SiO₂ target with an RF power of 10 to 115 Watts in an argon atmosphere. Other processes may be used as suits a particular phase change material and memory cell structure.

An optional annealing (not shown) can be performed to crystallize the phase change material. In the illustrated embodiment the thermal annealing step is carried out at 300° C. for 100 seconds in a nitrogen ambient. Alternatively, since subsequent back-end-of-line processes performed to complete the device may include high temperature cycles and/or a thermal annealing step depending upon the manufacturing techniques used to complete the device, in some embodiments the annealing may be accomplished by following processes, and no separate annealing step is added to the manufacturing line.

After formation of the body of phase change material, at step 615, a carbon deposit is deposited using for example sputtering using a “pure” carbon target. The sputtering can be executed in situ, in the same chamber as used for sputter deposition of the body of phase change material in some examples. Carbon deposit can be a continuous layer having a thickness of about 10 nm in some embodiments, as described in detail above.

Next, at step 620 a second electrode 140 is formed, resulting in the structure illustrated in FIG. 1. In the illustrated embodiment, the second electrode 140 comprises TiN.

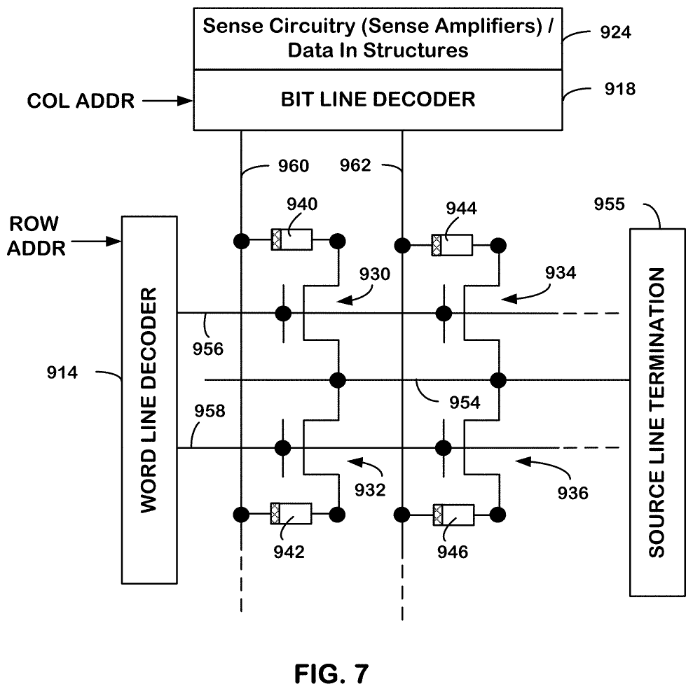

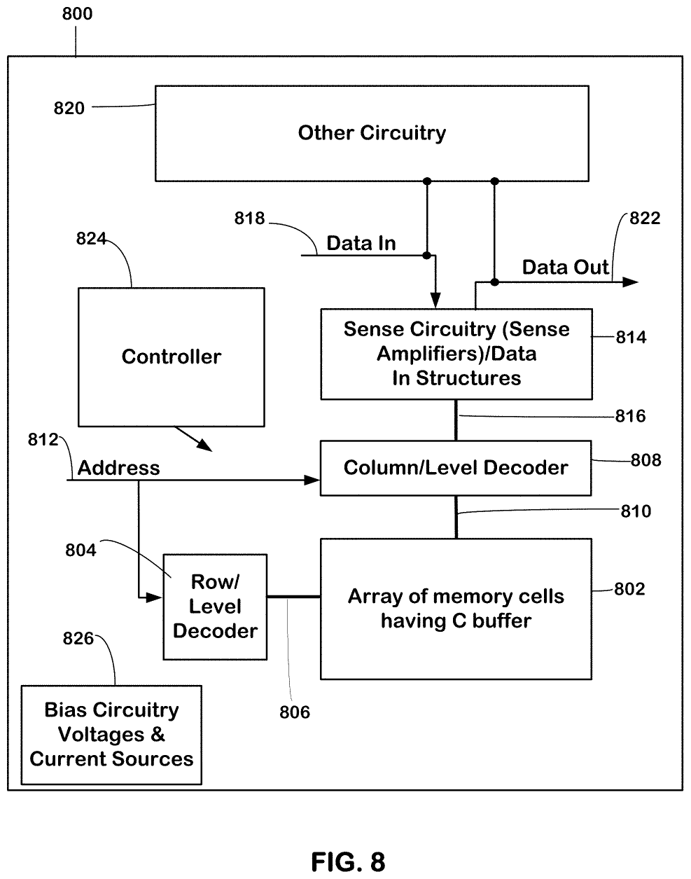

Next, at step 630 back-end-of-line (BEOL) processing is performed to complete the semiconductor process steps of the chip. The BEOL processes can be standard processes as known in the art, and the processes performed depend upon the configuration of the chip in which the memory cell is implemented. Generally, the structures formed by BEOL processes may include contacts, inter-layer dielectrics and various metal layers for interconnections on the chip including circuitry to couple the memory cell to peripheral circuitry. These BEOL processes may include deposition of dielectric material at elevated temperatures, such as depositing SiN at 400° C. or high density plasma HDP oxide deposition at temperatures of 500° C. or greater. As a result of these processes, control circuits and biasing circuits as shown in FIGS. 7 and 8 are formed on the device including, in some embodiments, circuitry for forming fast set and reset operations.

This process can be extended to 3D memory arrays, by forming multiple layers of memory array circuits.

In FIG. 7, four one-transistor, one memory element (1T/1R) memory cells 930, 932, 934, 936 having memory elements 940, 942, 944, 946 with carbon deposits between the body of phase change material and the top electrode are illustrated, representing a small section of an array.

Sources of each of the access transistors of memory cells 930, 932, 934, 936 are connected in common to first-type access line 954 (i.e. source line) that terminates in a source line termination of circuit 955, such as a ground terminal. In another embodiment, the source lines of the access devices are not shared between adjacent cells, but are independently controllable. The source line termination circuit 955 may include bias circuitry such as voltage sources and current sources, and decoding circuits for applying bias arrangements, other than ground, to the access line 954, in some embodiments.

A plurality of second-type access lines, including word lines 956, 958, extend in parallel along a first direction. Word lines 956, 958 are in electrical communication with word line decoder 914. The gates of access transistors of memory cells 930 and 934 are connected to word line 956, and the gates of access transistors of memory cells 932 and 936 are connected in common to word line 958.

A plurality of third-type access lines including bit lines 960, 962 extend in parallel in a second direction and are in electrical communication with bit line decoder 918, and sense amplifiers and data in circuits 924. In the illustrated embodiment, each of the memory elements are arranged between the drain of the corresponding access device and the corresponding bit line. Alternatively, the memory elements may be on the source side of the corresponding access device. Control circuitry and biasing circuits (see FIG. 8) are coupled to the array, and provide means for applying set and reset operations to the memory cells.

Alternatively, the memory cells can be organized in a cross-point architecture. The first electrode can be the access lines, such as word lines and/or bit lines. In such architecture, the access devices, such as diodes or OTS switches are arranged between the memory elements and the access lines.

FIG. 8 is a simplified block diagram of an integrated circuit 800 including a 3D array 802 of memory cells and with a carbon deposit forming a buffer layer as described above. A row/level line decoder 804 having read, set and reset modes is coupled to, and in electrical communication with, a plurality of word lines 806 arranged in levels and along rows in the array 802. A column/level decoder 808 is in electrical communication with a plurality of bit lines 810 arranged in levels and along columns in the array 802 for reading, setting, and resetting the memory cells in the array 802. Addresses are supplied on bus 812 to row/level decoder 804 and column/level decoder 808. Sense circuitry (Sense amplifiers) and data-in structures in block 814, including voltage and/or current sources for the read, set, and reset modes are coupled to column/level decoder 808 via data bus 816. Data is supplied via a data-in line 818 from input/output ports on integrated circuit 800, or from other data sources internal or external to integrated circuit 800, to data-in structures in block 814. Other circuitry 820 may be included on integrated circuit 800, such as a general purpose processor or special purpose application circuitry, or a combination of modules providing system-on-a-chip functionality supported by array 802. Data is supplied via a data-out line 822 from the sense amplifiers in block 814 to input/output ports on integrated circuit 800, or to other data destinations internal or external to integrated circuit 800.

A controller 824 implemented in this example, using a bias arrangement state machine, controls the application of bias circuitry voltage sources and current sources 826 for the application of bias arrangements, including fast read, set, reset and verify voltages, and/or currents for the word lines and bit lines. The controller includes control circuitry configured for switching layers having a threshold voltage depending on the structure and composition of the memory cells, by applying a voltage to a selected memory cell so that the voltage on the switch in the select memory cell is above the threshold, and a voltage to an unselected memory cell so that the voltage on the switch in the unselected memory cell is below the threshold during a read operation or other operation accessing the selected memory cell.

Controller 824 may be implemented using special-purpose logic circuitry as known in the art. In alternative embodiments, controller 824 comprises a general-purpose processor, which may be implemented on the same integrated circuit to execute a computer program to control the operations of the device. In yet other embodiments, a combination of special-purpose logic circuitry and a general-purpose processor may be utilized for implementation of controller 824.

In operation, each of the memory cells in the array 802 stores data depending upon the resistance of the corresponding memory element. The data value may be determined, for example, by comparison of current on a bit line for a selected memory cell to that of a suitable reference current by sense amplifiers of sense circuitry (block 814). The reference current can be established so that a predetermined range of currents correspond to a logical “0”, and a differing range of current corresponds to a logical “1”.

Reading or writing to a memory cell of array 802, therefore, can be achieved by applying a suitable voltage to bit lines using a voltage source so that current flows through the selected memory cell.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims. What is claimed is:

1. A memory device, comprising:
a memory element comprising a body of phase change material and a carbon deposit on the body of phase change material;
a first electrode contacting the body of phase change material; and
a second electrode contacting the carbon deposit.

2. The memory device of claim 1, wherein the first electrode contacts the body of phase change material over a first contact area, the second electrode contacts the carbon deposit over a second contact area, and the first contact area being smaller than the second contact area.

3. The memory device of claim 1, wherein the phase change material is a chalcogenide compound.

4. The memory device of claim 1, wherein the phase change material is a GaₓSb_{y}Te_{z} compound.

5. The memory device of claim 1, wherein the carbon deposit consists essentially of carbon.

6. The memory device of claim 1, wherein the carbon deposit is a layer having a thickness less than 15 nm.

7. The memory device of claim 1, including
a switching layer in series with the first electrode, the switching layer comprising an ovonic threshold switch material.

8. An integrated circuit comprising:
a memory array including plurality of memory cells on a substrate, memory cells in the array each comprising a memory element comprising a body of phase change material and a carbon deposit on the body of phase change material, a first electrode contacting the body of phase change material and a second electrode contacting the carbon deposit;
a first plurality of access lines in electrical series with the first electrodes of respective sets of memory cells in the array, and a second plurality of access lines in electrical series with respective sets of the second electrodes of memory cells in the array.

9. The integrated circuit of claim 8, wherein the first electrode contacts the body of phase change material over a first contact area, and the second electrode contacts the carbon deposit over a second contact area, the first contact area being smaller than the second contact area.

10. The integrated circuit of claim 8, wherein the phase change material is a chalcogenide compound.

11. The integrated circuit of claim 8, wherein the phase change material is a GaₓSb_{y}Te_{z} compound.

12. The integrated circuit of claim 8, wherein the carbon deposit consists essentially of carbon.

13. The integrated circuit of claim 8, wherein the carbon deposit is a layer having a thickness less than 15 nm.

14. The integrated circuit of claim 8, wherein the memory cells each include a switching layer in series between the first electrode and one of the second access lines, the switching layer comprising an ovonic threshold switch material.

15. The integrated circuit of claim 8, wherein the memory cells in the array each include an access device between the first electrode and one of the first access lines.

16. A memory device, comprising:
a memory element comprising a body of programmable resistance material and a carbon deposit on a body of phase change material;
a first electrode contacting the body of phase change material; and
a second electrode contacting the carbon deposit.
